(19) United States
(12) Patent Application Publication
(10) Pub. No.: US 2005/0179924 A1
(43) Pub. Date: Aug. 18, 2005

(54) Option module using clock frequency, electric device, and methods therefor

(75) Inventor: Yeo-phil Yoon, Suwon-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRONICS CO., LTD., Suwon-si (KR)

(21) Appl. No.: 11/036,350

(22) Filed: Jan. 18, 2005

(30) Foreign Application Priority Data
Jan. 20, 2004 (KR) 2004-4280

(51) Int. Cl. G06F 3/12; H05K 7/00; H05K 9/00; G01R 23/02

(52) U.S. Cl. 358/1.13; 327/47; 361/728; 361/734; 333/172

(57) ABSTRACT

An option module using a clock frequency, an electric device, and methods therefor. The option module is connectable to a main module and provides an additional function, and includes a power supply supplying a power, a clock generator receiving the power from the power supply and generating a clock having a particular frequency, and an interface chip interfacing the power supply and the clock generator and outputting the particular clock generated in the clock generator to the main module. As the option module is implemented with the simple signal protection circuit, the option module is profitable and expandable to various option module types with varying functions.

### CROSS-REFERENCE TO RELATED APPLICATIONS

This application claims the benefit of Korean Patent Application No. 2004-4280, filed Jan. 20, 2004 in the Korean Intellectual Property Office, the disclosure of which is incorporated herein by reference in its entirety.

### BACKGROUND OF THE INVENTION

1. Field of the Invention

The present invention is generally related to an option module using a clock frequency, an electric device, and methods therefore. More particularly, the present invention pertains to an option module for providing compatibility between a multi-function device and the option module using a clock frequency, an electric device, and methods therefor.

2. Description of the Related Art

In general, a multi-function device what is called, a multi-function peripheral (MFP), integrates separate functions of office machines such as a facsimile machine, a scanner, a printer, and a copier, into a single terminal. The multi-function device can usually be independently used or connected to a computer.

By way of example, a copier is described below.

FIG. 1 is a function block diagram of a conventional digital copier. The conventional digital copier includes a scanning part 1 for scanning an image of a document, a cartridge 2 containing sheets of paper, a print part 3 for printing an image on a sheet of paper, and an operation panel 8 for controlling operations of the digital copier.

The operation panel 8 includes a key input part 4 for inputting commands of a user, a displayer 6 for displaying the sheet image and a print image of a scanned document image on the sheet image, and a controller 5 for carrying out overall control operations.

An option module having various additional functions can be mounted to the operation panel 8, to provide the user with additional conveniences. To permit a user to utilize a mounted option module, the digital copier needs to detect the mounted option module and allow the option module to perform its additional functions.

FIGS. 2A and 2B illustrate conventional methods for detecting the option module.

FIG. 2A is a diagram of a conventional option module. The option module includes a first and a second resistor R1 and R2, and a switching transistor Q1. When the option module is mounted to the digital copier and power is applied to the digital copier, the digital copier detects the connection of the option module based on a voltage level of a connecting point M between the second resistor R2 and a collector of the switching transistor Q1. However, only the connection of the option module, not a type of the option module, is detected.

FIG. 2B is a diagram of another conventional option module. The option module includes a fourth resistor R4 which divides an applied voltage. The fourth resistor R4 divides the voltage with a third resistor R3 of a main module, separate from the option module, for example, the main module of a digital copier or a multi function machine, and supplies a particular voltage to the main module. The main module is provided with the particular voltage by way of an analog input terminal, and detects the type of the mounted option module by an analog-to-digital conversion. However, this option module requires the analog input terminal.

In addition, the above conventional option modules do not ensure stable operations when the option module is mounted to the main module, and are therefore unreliable and cannot provide full compatibility.

### SUMMARY OF THE INVENTION

To address the above drawbacks of the conventional arrangement, an aspect of the present invention is to provide an option module which can be mounted to a main module through a general input/output terminal and operate stably with the main module using a clock frequency, an electric device using the same, and methods therefor.

Additional aspects and/or advantages of the invention will be set forth in part in the description which follows and, in part, will be obvious from the description, or may be learned by practice of the invention.

Another exemplary aspect of the present invention is to provide an option module which uses a clock frequency providing full compatibility between a main module and the option module by stably detecting the connection and a type of the option module, and an electric device using the same.

To achieve the above and/or other aspects and advantages, embodiments of the present invention set forth an option module having a clock frequency and connectable to a main module, to provide an additional function to the main module, the option module including a clock generator generating a clock having a particular frequency, and an interface interfacing with the clock generator and outputting the particular frequency clock generated in the clock generator to the main module to identify the option module to the main module.

The option module may further include a circuit protector stabilizing and outputting the particular clock frequency, input from the interface, to the main module, and protecting circuit elements of the option module. The circuit protector may include a buffer protecting the clock generator and the interface, and a filter stabilizing and outputting the clock, with the filter being a resistor-capacitor (RC) filter. The circuit elements may also include the interface, with the interface being an interface chip, with the circuit protector protecting circuit elements in the option module from shocks.

In addition, the main module may be included in, and/or compatible with, one of a copier, a printer, a multi-function machine, and a facsimile machine. Similarly, the option module may include at least one of functions of transmitting e-mails and operating as a one-touch dial key for selecting phone numbers or fax numbers.

The option module may also include a power supply supplying power to the clock generator through the interface, with the interface being an interface chip.

To achieve the above and/or other aspects and advantages, embodiments of the present invention set forth an electric device including a first module performing a main function of the electric device, and a removable second module, connected to the first module, performing an additional function for the electric device, wherein the first module controls performance of the additional function of the second module based on a clock signal generated in the second module, with the clock signal being discriminated outside of the second module.

The first module may detect a clock frequency generated in the second module, and the electric device may include a connector connecting the first module and the second module.

In addition, the second module may be distinguishable from a different module replacing the second module by a different clock signal generated in the different module, wherein the second module may also provide the first module with additional functionality differently than functionality provided by the different module.

The electric device may further include corresponding stored recognition data corresponding to different clocks of the second and different modules, and application programs, with the stored recognition data being used to distinguish the second module from the different module and an appropriate program, of the application programs, providing the electric device compatibility with the distinguished second or different module. In addition, an application program for the second module may be different from an application for the different module.

To achieve the above and/or other aspects and advantages, embodiments of the present invention set forth an electric device supporting removable second modules, connectable to a first module, for performing additional functions for the electric device, with different removable second modules providing differing additional functions, including the first module performing a main function of the electric device, wherein the first module is configured to control performance of an additional function of an attached second module based on a clock signal generated in the attached second module and particular to the attached second module compared to other attachable second modules, with the clock signal of the attached second module being discriminated outside of the attached second module.

To achieve the above and/or other aspects and advantages, embodiments of the present invention set forth a method of providing additional functions to an electric device, the electric device supporting removable second modules, connectable to a first module, for performing additional functions for the electric device, with different removable second modules providing differing additional functions, including performing a main function of the electric device, and controlling performance of an additional function of an attached second module based on a clock signal generated in the attached second module and particular to the attached second module compared to other attachable second modules, with the clock signal of the attached second module being discriminated outside of the attached second module.

To achieve the above and/or other aspects and advantages, embodiments of the present invention set forth a method of providing additional functions to an electric device, the electric device supporting removable second modules, connectable to a first module, for performing additional functions for the electric device, with different removable second modules providing differing additional functions, including generating a clock signal in a second module to be provided to the electric device, with a performance of an additional function of the second module being based on the generated clock signal, particular to the second module compared to other second modules, based on the clock signal of the second module being discriminated outside of the second module. The method may further include providing circuit protection to the second module to protect circuits inside the second module from shock upon attachment to the electric device.

### BRIEF DESCRIPTION OF THE DRAWINGS

These and/or other aspects and advantages of the invention will become apparent and more readily appreciated from the following description of the embodiments, taken in conjunction with the accompanying drawing figures of which:

FIG. 1 is a function block diagram illustrating a conventional digital copier;

FIGS. 2A and 2B are diagrams illustrating conventional methods for detecting an option module;

FIG. 3 is an internal circuit diagram illustrating an option module using a clock frequency, according to an embodiment of the present invention;

FIG. 4 is a block diagram illustrating an operation panel of an electric device, according to an embodiment of the present invention;

FIG. 5 is a block diagram illustrating an option module detecting device of FIG. 4, according to an embodiment of the present invention; and

FIG. 6 is a flowchart illustrating operations of an option module detecting method, according to an embodiment of the present invention.

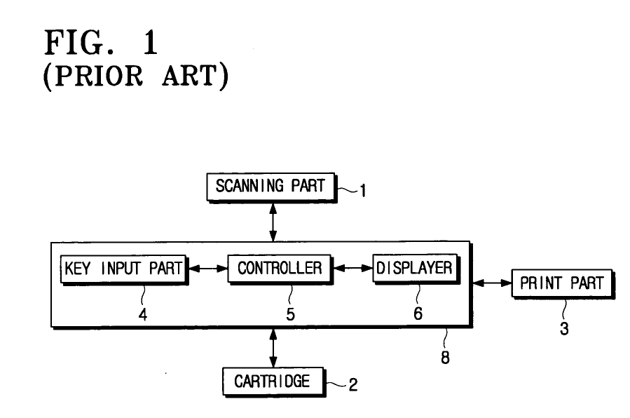

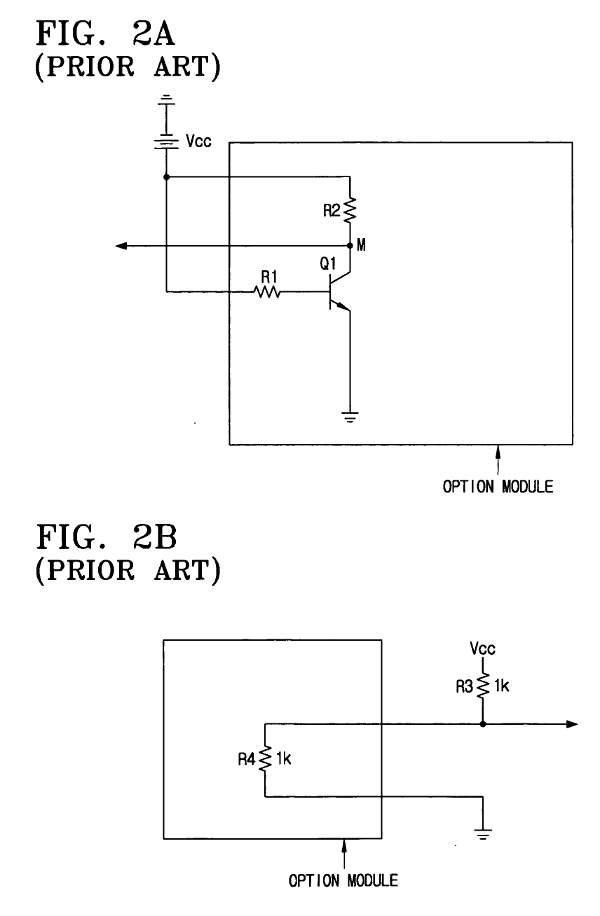

### DETAILED DESCRIPTION OF THE PREFERRED EMBODIMENTS

Reference will now be made in detail to embodiments of the present invention, examples of which are illustrated in the accompanying drawing figures, wherein like reference numerals refer to the like elements throughout. The embodiments are described below in order to explain the present invention by referring to the drawing figures.

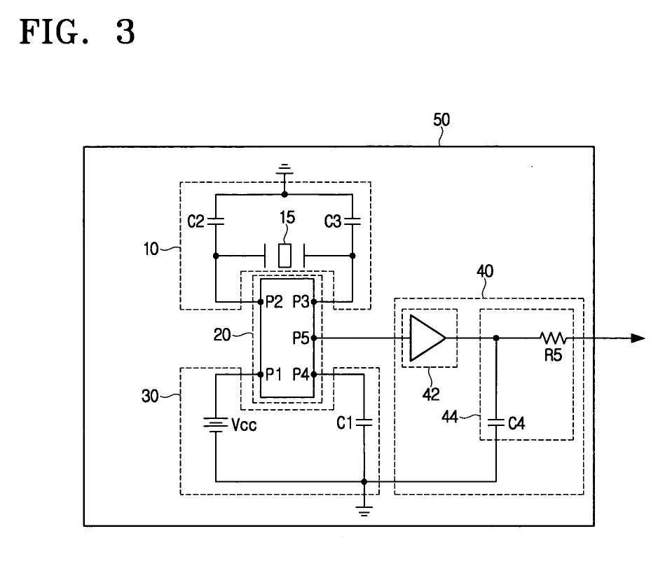

FIG. 3 is an internal circuit diagram illustrating an option module using a clock frequency, according to an embodiment of the present invention. The internal circuit of the option module 50 includes a power supply 30, a clock generator 10, a circuit protector 40, and an interface chip 20.

The power supply 30 provides power to the entire circuit, including the clock generator 10. The clock generator 10 generates a clock having a certain frequency using oscillation of a crystal 15. The frequency of the crystal 15 depends on a type of the option module 50.

The interface chip 20 includes a plurality of an input/output ports P1 to P5, for example. The interface chip 20 interfaces the power supply 30, the clock generator 10, and the circuit protector 40 so as to apply voltage Vcc to the clock generator 10 and the circuit protector 40. The interface chip 20 also interfaces the clock generator 10 and the circuit protector 40 so as to input to the circuit protector 40 a particular clock, of a plurality of clocks, generated in the clock generator 10 through the port P5 of the interface chip 20.

The circuit protector 40 includes a buffer 42 and a resistor-capacitor (RC) filter 44. The buffer 42 prevents the circuit elements from shocks, such as a surge to the crystal 15 when the user mounts the option module 50 while an electric device, e.g., a digital copier, is turned on. The RC filter 44 stabilizes and outputs the clock.

As constructed above, the option module 50 can be variously implemented, e.g., as an option module transmitting e-mails, an option module functioning as one-touch dial keys for selecting phone numbers or fax numbers, or an option module having expanded functions of the operation panel of a main module.

The user can easily mount or dismount the option module 50, and the option module 50 can be connected to a main module through a single connector. As an example, the main module refers to a copier, a printer, a multi-function machine, and a facsimile machine.

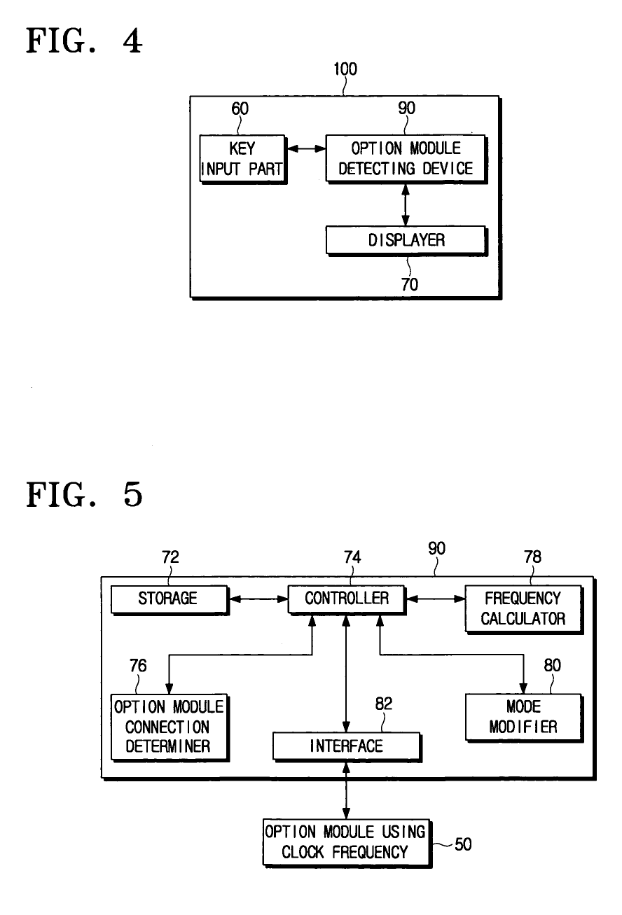

FIG. 4 is a block diagram of an operation panel of an electric device, according to an embodiment of the present invention. The operation panel 100 includes an option module detecting device 90, a key input part 60, and a displayer 70. The displayer 70 may be a liquid crystal display (LCD) or a light emitting diode (LED).

FIG. 5 is a block diagram of the option module detecting device 90 of FIG. 4.

Referring to FIGS. 4 and 5, the option module detecting device 90 includes a controller 74, a storage 72, an option module connection determiner 76, an interface (connector 82), a frequency calculator 78, and a mode modifier 80.

When the user wishes to mount the option module 50, which has a specific function such as a one-touch key of a fax machine or an e-mail keyboard of a copier, to the operation panel 100 of the main module (not shown), the option module connection determiner 76 determines whether the option module 50 is connected through the connector 82 and what type of option module has been connected. The connection is determined by detecting a clock having a particular frequency, generated in the option module 50.

The frequency calculator 78 can acquire the frequency of the clock generated by the option module 50 by counting the clock of the certain frequency generated in the option module 50.

The frequency generated by the option module 50 can thus be acquired by counting a time between a first rising edge and a next rising edge of an input clock, or, by counting a time between a first rising edge and a first falling edge of the input clock, for example. The frequency calculator 78 is preferably a software-implemented timer, but is not limited thereto.

The storage 72 pre-stores option module recognition data and application programs with respect to different types of option modules, i.e., with differing types corresponding to a one-touch key of a fax machine or an e-mail keyboard for a copier, for example. The option module recognition data permits the main module to distinguish the type of the option module 50 depending on each frequency. The appropriate application programs then provide compatibility between the option module 50 and the main module.

The controller 74 detects the type of the option module by comparing and analyzing the option module recognition data pre-set in the storage 72 and the clock frequency calculated in the frequency calculator 78.

The mode modifier 80 can then modify a mode of the main module to a certain mode corresponding to the option module by executing application programs corresponding to the detected option module 50 so that the option module 50 operates compatibly with the main module.

For instance, when the option module 50 has the one-touch key function and is mounted and connected to a digital copier, the option module 50 may generate a clock frequency of 5 Khz. Accordingly, option module recognition data can contain pre-set information indicating that the option module 50, generating the 5 KHz clock frequency, has the one-touch key function.

When the controller 74 detects this information of the mounted option module 50, using the pre-set option module recognition data, the mode modifier 80 modifies the mode of the main module in correspondence with the option module 50 by executing application programs which provides the compatibility between the option module 50 and the digital copier.

In an embodiment of the present invention, the application programs denote software that enable the option module 50, having the one-touch key function to compatibly operate in the digital copier, for example.

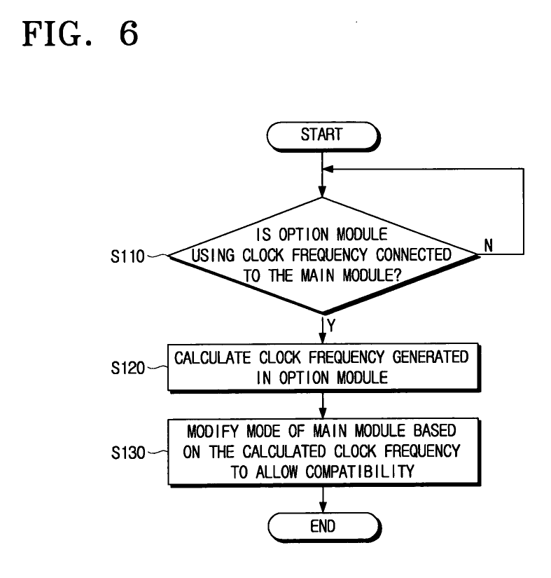

FIG. 6 is a flowchart illustrating exemplary operations of the option module detecting device 90, according to an embodiment of the present invention. Referring to FIG. 6, it is determined whether the option module 50, using the detection of a clock frequency, is connected to the main module, in operation S110. If so, the clock frequency of the option module 50 is calculated, in operation S120. The mode of the main module is modified in correspondence with the option module 50, depending on the calculated clock frequency, in operation S130.

As a result, the option module recognition device 90 provides compatibility between the option module 50 and the main module.

In light of the foregoing, since the option module 50 is implemented with the simple signal protection circuit, the option module 50 can be profitable and expandable to various option module types. Since various option modules can be distinguished based on each corresponding frequency, and the option module 50 can stably operate with the main module, full compatibility can be ensured between the option module 50 and the main module.

While the embodiments of the present invention have been described, additional variations and modifications of the embodiments may occur to those skilled in the art once they learn of the basic inventive concepts. Therefore, it is intended that the appended claims shall be construed to include both the above embodiments and all such variations and modifications that fall within the spirit and scope of the invention.

Accordingly, although a few embodiments of the present invention have been shown and described, it would be appreciated by those skilled in the art that changes may be made in these embodiments without departing from the principles and spirit of the invention, the scope of which is defined in the claims and their equivalents.

1. An option module having a clock frequency and connectable to a main module, to provide an additional function to the main module, the option module comprising:
a clock generator generating a clock having a particular frequency; and
an interface interfacing with the clock generator and outputting the particular frequency clock generated in the clock generator to the main module to identify the option module to the main module.

2. The option module of claim 1, further comprising a circuit protector stabilizing and outputting the particular clock frequency, input from the interface, to the main module, and protecting circuit elements of the option module.

3. The option module of claim 2, wherein the circuit protector comprises:
a buffer protecting the clock generator and the interface; and
a filter stabilizing and outputting the clock.

4. The option module of claim 3, wherein the filter is a resistor-capacitor (RC) filter.

5. The option module of claim 2, wherein the circuit elements comprise the interface, with the interface being an interface chip.

6. The option module of claim 2, wherein the circuit protector protects circuit elements in the option module from shocks.

7. The option module of claim 1, wherein the main module is comprised in, and/or compatible with, one of a copier, a printer, a multi-function machine, and a facsimile machine.

8. The option module of claim 1, wherein the option module includes at least one of functions of transmitting e-mails and operating as a one-touch dial key for selecting phone numbers or fax numbers.

9. The option module of claim 1, further comprising a power supply supplying power to the clock generator through the interface.

10. The option module of claim 1, wherein the interface is an interface chip.

11. An electric device comprising:
a first module performing a main function of the electric device; and
a removable second module, connected to the first module, performing an additional function for the electric device,
wherein the first module controls performance of the additional function of the second module based on a clock signal generated in the second module, with the clock signal being discriminated outside of the second module.

12. The electric device of claim 11, wherein the first module detects a clock frequency generated in the second module.

13. The electric device of claim 11, further comprising a connector connecting the first module and the second module.

14. The electric device of claim 11, wherein the first module is one of a copier, printer, a multi-function machine, and a facsimile machine.

15. The electric device of claim 11, wherein the second module is distinguishable from a different module replacing the second module by a different clock signal generated in the different module.

16. The electric device of claim 15, wherein the second module provides the first module with additional functionality differently than functionality provided by the different module.

17. The electric device of claim 15, further comprising:
corresponding stored recognition data corresponding to different clocks of the second and different modules; and
application programs, with the stored recognition data being used to distinguish the second module from the different module and an appropriate program, of the application programs, providing the electric device compatibility with the distinguished second or different module.

18. The electric device of claim 17, wherein an application program for the second module is different from an application for the different module.

19. An electric device supporting removable second modules, connectable to a first module, for performing additional functions for the electric device, with different removable second modules providing differing additional functions, comprising:
the first module performing a main function of the electric device,
wherein the first module is configured to control performance of an additional function of an attached second module based on a clock signal generated in the attached second module and particular to the attached second module compared to other attachable second modules, with the clock signal of the attached second module being discriminated outside of the attached second module.

20. A method of providing additional functions to an electric device, the electric device supporting removable second modules, connectable to a first module, for performing additional functions for the electric device, with different removable second modules providing differing additional functions, comprising:
performing a main function of the electric device; and
controlling performance of an additional function of an attached second module based on a clock signal generated in the attached second module and particular to the attached second module compared to other attachable second modules, with the clock signal of the attached second module being discriminated outside of the attached second module.

21. A method of providing additional functions to an electric device, the electric device supporting removable second modules, connectable to a first module, for performing additional functions for the electric device, with different removable second modules providing differing additional functions, comprising:
generating a clock signal in a second module to be provided to the electric device, with a performance of an additional function of the second module being based on the generated clock signal, particular to the second module compared to other second modules, based on the clock signal of the second module being discriminated outside of the second module.

22. The method of claim 21, further comprising providing circuit protection to the second module to protect circuits inside the second module from shock upon attachment to the electric device.
